(19) United States
(12) Patent Application Publication
(10) Pub. No.: US 2026/0006730 A1
(43) Pub. Date: Jan. 1, 2026

(54) SPLICED DISPLAY

(71) Applicant: AUO Corporation, Hsinchu City (TW)

(72) Inventors: Jyun-Jang HE, Hsinchu City (TW); Wen-Lin CHENG, Hsinchu City (TW); Wei-Ting HSU, Hsinchu City (TW)

(21) Appl. No.: 18/977,047

(22) Filed: Dec. 11, 2024

(30) Foreign Application Priority Data
Jun. 26, 2024 (TW) 113123895

(51) Int. Cl. H05K 5/02; H05K 5/30

(52) U.S. Cl. CPC H05K 5/0217; H05K 5/30

(57) ABSTRACT

A spliced display includes a plurality of display modules and at least one angle limiting assembly. Each display module includes a box and a display. A direction perpendicularly connected to a display side and a back side of the box is defined as a first direction. The display is detachably disposed on the display side of the box. The angle limiting assembly includes a rotation member, a linkage assembly and a connector. The rotation member is rotatably disposed on the box around a second direction perpendicular to the first direction, and has a guiding portion. The linkage assembly is disposed on the rotation member, and includes a linkage portion. When the rotation member rotates, the linkage portion is guided by the guiding portion to linearly move along the second direction. The connector is connected to the linkage assembly. Each display module abuts against an adjacent display module by the connector.

### CROSS-REFERENCE TO RELATED PATENT APPLICATION

This non-provisional application claims priority to and the benefit of, pursuant to 35 U.S.C. § 119(a), patent application No. 113123895 filed in Taiwan on Jun. 26, 2024. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to a display device, and in particular to a spliced display.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A spliced display is a large display formed by splicing a plurality of display modules. Each display module mainly includes a frame and a plurality of displays, and the displays are disposed at the front side of the frame to form a display surface. When an individual display requires maintenance, to minimize the impact on the display surface, a maintenance frame is typically installed on the back side of the entire spliced display for a maintenance personnel to perform the operation. When an individual display requires disassembling and repair, the display is usually separated from the frame toward the front side and thus adjusted its angle, and after the angle adjustment, the display is moved from the inner space of the frame to the back side for the maintenance personnel to perform the maintenance.

However, in the conventional spliced display, to achieve a specific included angle, it often includes an angle limiting assembly between the display modules to adjust the inter-module angle between adjacent display modules, and the angle limiting assembly to adjust the inter-module angle between adjacent display modules typically occupies a significant space inside the frame, thus severely restricting the angle at which the display is moved from the front side to the back side, causing the process of disassembling an individual display to become challenging. Consequently, when an individual display is damaged, due to the difficulty of disassembly of the individual display, the time cost considerations often cause the disposal of the entire display modules even when other displays remain functional, thus resulting in unnecessary waste and significant waste of resources.

### SUMMARY

In one aspect, the present disclosure provides a spliced display, which includes a plurality of display modules and an angle limiting assembly. Each display module includes a box and a display. The box includes a display side and a back side opposite to each other, and a direction perpendicularly connected to the display side and the back side is defined as a first direction. The display is detachably disposed on the display side of the box. The angle limiting assembly includes a rotation member, a linkage assembly and a connector. The rotation member is rotatably disposed on the box around a second direction perpendicular to the first direction. The rotation member has a guiding portion, and two ends of the guiding portion are located at different positions in the second direction. The linkage assembly includes a linkage portion, and the linkage assembly is disposed on the rotation member. When the rotation member rotates, the linkage portion is guided by the guiding portion to linearly move along the second direction. The connector is connected to the linkage assembly. Each display module abuts against an adjacent one of the display modules by the connector.

As such, the rotation axis around which the angle limiting assembly rotates is arranged in a direction parallel to the display, which allows the angle limiting assembly to be installed around the periphery of the box, reducing the space being occupied inside the box, thus improving the ease of installation, removal, or maintenance of the display, extending the lifespan of the product, and achieving the effect of a circular economy.

In certain embodiments, the spliced display further includes a fixing member, the box includes a first side edge and a second side edge opposite to each other, the angle limiting assembly is located on the first side edge, the fixing member is disposed on the second side edge, the first side edge of one of the display modules abuts against the second side edge of the adjacent one of the display modules, and the fixing member fixes two adjacent ones of the display modules.

In certain embodiments, the guiding portion is a slot, the linkage assembly further comprises a swing arm, the linkage portion comprises a recess and a rolling ball, the recess is disposed on the swing arm, the rolling ball is rollably disposed within the guiding portion, and the swing arm sleeves over the rolling ball via the recess.

In certain embodiments, a side of the first side edge of the box facing toward the second side edge is an inner side, the other side of the first side edge is an outer side, the rotation member comprises a first body section and a second body section interconnected to each other, the first body section abuts against the inner side of the first side edge, and the second body section is disposed on the first side edge.

In certain embodiments, the first side edge of the box further comprises a position limiting slot, the position limiting slot extends along the second direction and is open at the outer side of the box, the linkage assembly further comprises a swing arm, the swing arm has a position limiting portion, and the position limiting portion is movably accommodated in the position limiting slot along the second direction.

In certain embodiments, the angle limiting assembly further includes a compressive assembly disposed at the inner side and abutting against a side of the swing arm away from the rotation member, and the compressive assembly compresses the swing arm and the rotation member along the first direction.

In certain embodiments, the guiding portion is a slot.

In certain embodiments, the spliced display further includes a positioning module, disposed between the box and the rotation member to position the rotation member.

In certain embodiments, the positioning module includes a first positioning hole, a plurality of second positioning holes and a pin, the first positioning hole is disposed on the box, each of the second positioning holes is disposed on the rotation member, and the pin passes through one of the second positioning holes and the first positioning hole to fix the rotation member at different angular positions.

In certain embodiments, the positioning module includes a plurality of positioning slots, an elastic body and a positioning member, the positioning slots are disposed on a peripheral surface of the rotation member, one end of the elastic body is fixed to the box, one end of the positioning member is connected to the other end of the elastic body, the other end of the positioning member is detachably accommodated in one of the positioning slots, and a position between the two ends of the positioning member is pivoted to the box.

In certain embodiments, the positioning module includes a plurality of teeth, a worm gear and a driving source, each of the teeth is disposed along a peripheral surface of the rotation member, the driving source is fixed to the box, and the worm gear is connected to the driving source and engages with the teeth on the rotation member.

These and other aspects of the present disclosure will become apparent from the following description of the embodiment taken in conjunction with the following drawings, detailed description and the claims.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective appearance schematic view of a spliced display according to one embodiment of the present disclosure.

FIG. 2 is a perspective appearance schematic view of a display module of a spliced display according to one embodiment of the present disclosure.

FIG. 3 is a perspective appearance schematic view of a display module of a spliced display from another viewing angle according to one embodiment of the present disclosure.

FIG. 4 is a first usage schematic view of an angle limiting assembly of the display module of a spliced display according to one embodiment of the present disclosure.

FIG. 5 is a second usage schematic view of an angle limiting assembly of the display module of a spliced display according to one embodiment of the present disclosure.

FIG. 6 is a third usage schematic view of an angle limiting assembly of the display module of a spliced display according to one embodiment of the present disclosure.

FIG. 7 is a plain schematic view of a spliced display according to one embodiment of the present disclosure, illustrating a first schematic view of the angle adjustment of adjacent display modules.

FIG. 8 is a cross-sectional view along the sectional line 8-8 in FIG. 7.

FIG. 9 is a partial enlarged schematic view of enclosed location 9 in FIG. 8.

FIG. 10 is a state schematic view of the fixing member in FIG. 9 being released.

FIG. 11 is a plain schematic view of a spliced display according to one embodiment of the present disclosure, illustrating a second schematic view of the angle adjustment of adjacent display modules.

FIG. 12 is a cross-sectional view along the sectional line 12-12 in FIG. 11.

FIG. 13 is a partial enlarged schematic view of enclosed location 13 in FIG. 12.

FIG. 14 is a partial enlarged schematic view of enclosed location 14 in FIG. 2.

FIG. 15 is a schematic view of a display module of a spliced display according to one embodiment of the present disclosure, illustrating the display module including a positioning module capable of performing automatic positioning.

FIG. 16 is a partial enlarged schematic view of enclosed location 16 in FIG. 15.

FIG. 17 is a partial plain view of FIG. 15.

FIG. 18 is a schematic view of a display module of a spliced display according to one embodiment of the present disclosure, illustrating a positioning module capable of freely adjusting the angle.

FIG. 19 is a partial enlarged schematic view of enclosed location 19 in FIG. 18.

FIG. 20 is a partial plain view of FIG. 18.

### DETAILED DESCRIPTION

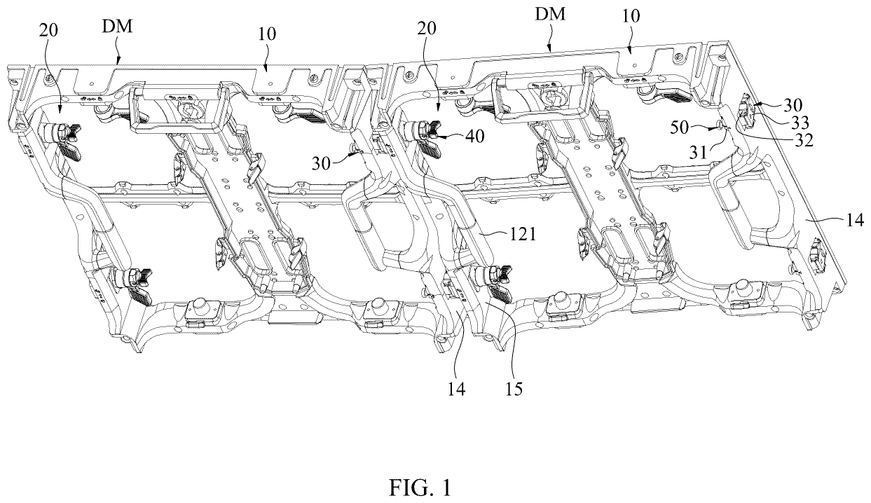

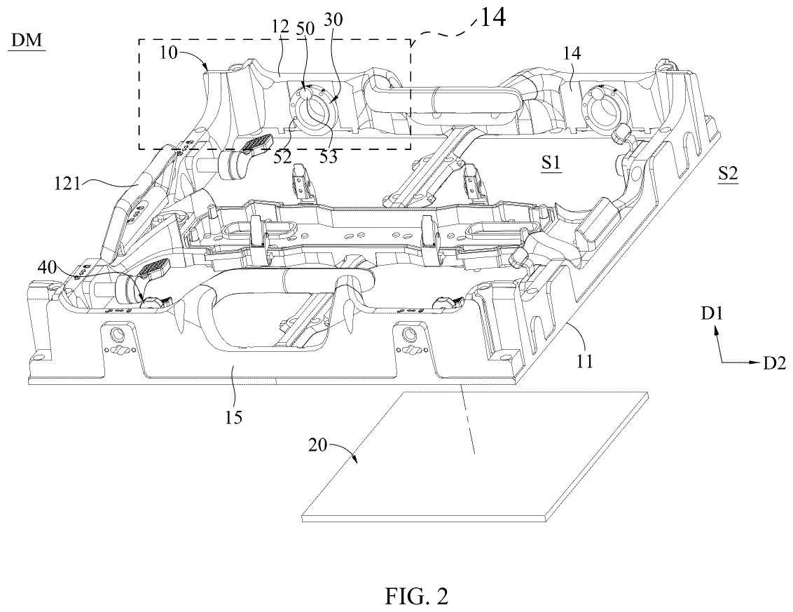

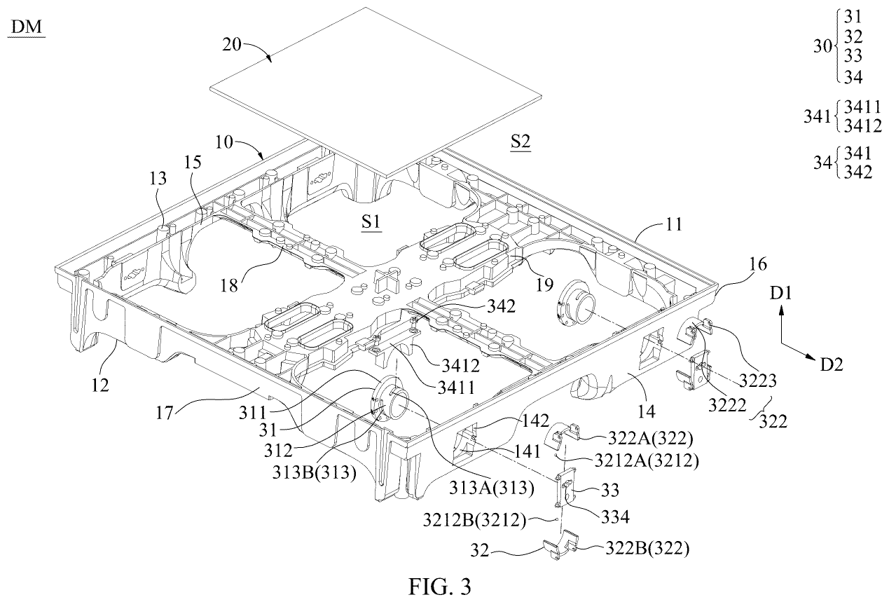

Referring to FIGS. 1 to 3, FIG. 1 is a perspective appearance schematic view of a spliced display according to one embodiment of the present disclosure; FIG. 2 is a perspective appearance schematic view of a display module of a spliced display according to one embodiment of the present disclosure; and FIG. 3 is a perspective appearance schematic view of a display module of a spliced display from another viewing angle according to one embodiment of the present disclosure. The present disclosure provides a spliced display, which includes a plurality of display modules DM being spliced to each other. The display modules DM are adjacent and spliced together, and an included angle between the adjacent display modules DM is limited by an angle limiting assembly 30, thus providing a spliced display that may change the splicing angle. Referring to FIGS. 1 to 4, FIG. 4 is a first usage schematic view of an angle limiting assembly of the display module of a spliced display according to one embodiment of the present disclosure. Each display module DM includes a box 10 and a display 20. The box 10 includes a display side 11 and a back side 12 opposite to each other, and a direction perpendicularly connected to the display side 11 and the back side 12 is defined as a first direction D1. The display 20 is detachably disposed on the display side 11 of the box 10. The angle limiting assembly 30 includes a rotation member 31, a linkage assembly 32 and a connector 33. The rotation member 31 is rotatably disposed on the box 10 around a second direction D2 perpendicular to the first direction D1. The rotation member 31 has a guiding portion 313, and two ends of the guiding portion 313 are located at different positions in the second direction D2. The linkage assembly 32 includes a linkage portion 321, and the linkage assembly 32 is disposed on the rotation member 31. When the rotation member 31 rotates, the linkage portion 321 is guided by the guiding portion 313 to linearly move along the second direction D2. The connector 33 is connected to the linkage assembly 32. Each display module DM abuts against an adjacent one of the display modules DM by the connector 33.

As such, the rotation axis around which the angle limiting assembly 30 rotates is arranged in a direction parallel to the display 20, which allows the angle limiting assembly 30 to be installed around the periphery of the box 10, reducing the space being occupied inside the box 10, thus improving the ease of installation, removal, or maintenance of the display 20, extending the lifespan of the product, and achieving the effect of a circular economy.

Referring to FIGS. 2 and 3, the box 10 is a rectangular hollow frame structure used to support the display 20. In certain embodiments, the contour of the display side is rectangular. The box 10 further has an inner edge 13. In the first direction D1, the inner edge 13 is closer to the display side 11 than the back side 12, and the display 20 abuts against the inner edge 13 to be disposed to be coplanar to the display side 11. In certain embodiments, the inner edge 13 may be disposed with a magnetic member, which magnetically secure and position the display 20.

Referring to FIGS. 2 and 3, in certain embodiments, the box 10 further includes a first side edge 14, a second side edge 15, a third side edge 16 and a fourth side edge 17. The first side edge 14 is parallel and opposite to the second side edge 15. The third side edge 16 is parallel and opposite to the fourth side edge 17, and both are respectively connected between two ends of the first side edge 14 and the second side edge 15. In these embodiments, a side of the box 10 surrounded by the first side edge 14, the second side edge 15, the third side edge 16 and the fourth side edge 17 is an inner side S1, and the remaining portion is an outer side S2. The display 20 is disposed in the inner side S1 of the box 10.

Referring to FIGS. 2 and 3, the box 10 of each display module DM may be, without being limited thereto, disposed with a single display 20 or multiple displays 20. In certain embodiments as shown in FIGS. 2 and 3, the box 10 of the display module DM may be disposed with four displays 20 (and only one display 20 is illustrated in FIG. 3). In these embodiments, the box 10 further includes a first supporting member 18 and a second supporting member 19. The first supporting member 18 is connected between the first side edge 14 and the second side edge 15 and is parallel to the third side edge 16 and the fourth side edge 17, and the second supporting member 19 is connected between the third side edge 16 and the fourth side edge 17 and is parallel to the first side edge 14 and the second side edge 15. Thus, the inner side S1 of the box 10 is divided into four regions for disposing the four displays 20. As such, the first supporting member 18 and the second supporting member 19 may be disposed with magnetic members to magnetically secure and position each display 20.

Referring to FIG. 2, in certain embodiments, the back side 12 of the box 10 may be disposed with a handle 121. Thus, when an operator performs detaching of the display 20, the operator may grip the handle 121 and apply a force to push the display 20 in a direction away from the display side 11, and rotate the display 20 to an angle that allows it to pass the box 10 when the display 20 is pushed to a position no longer magnetically held by the magnetic force of the box 10. Then, the display 20 may be moved from the display side 11 to the back side 12 to perform maintenance or replacement.

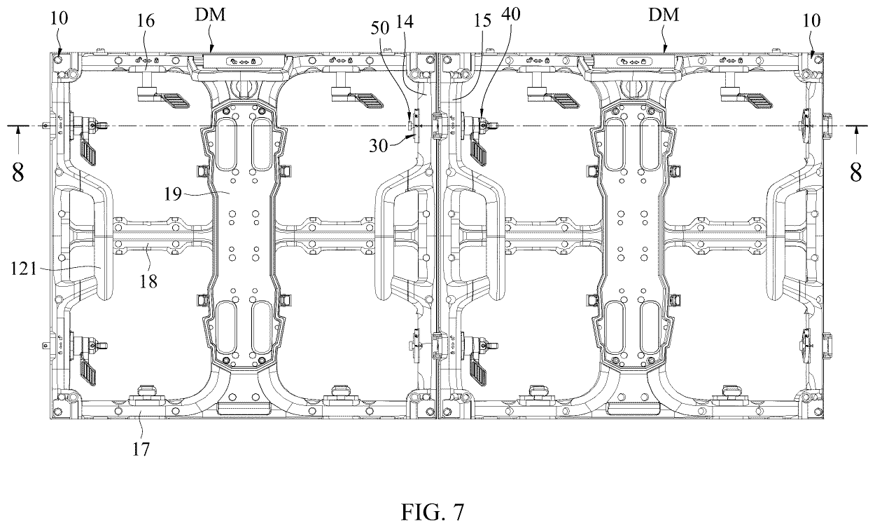

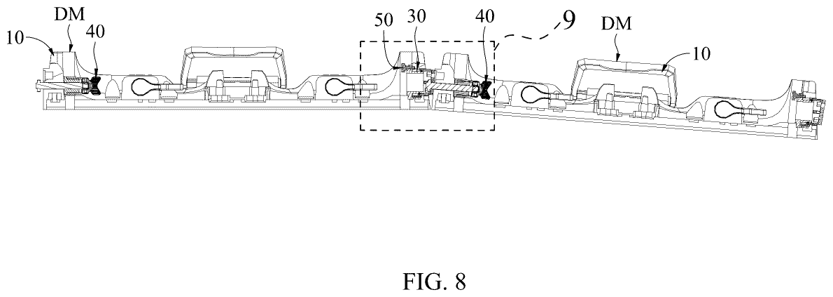

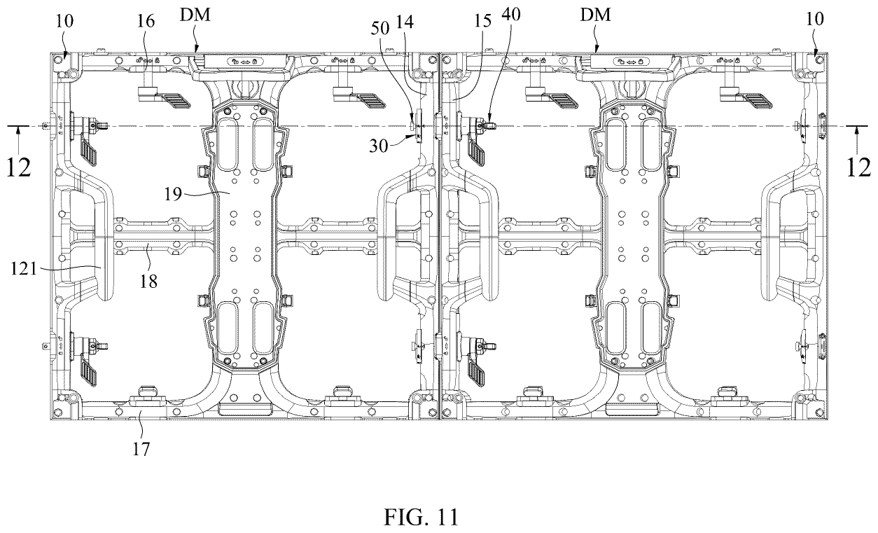

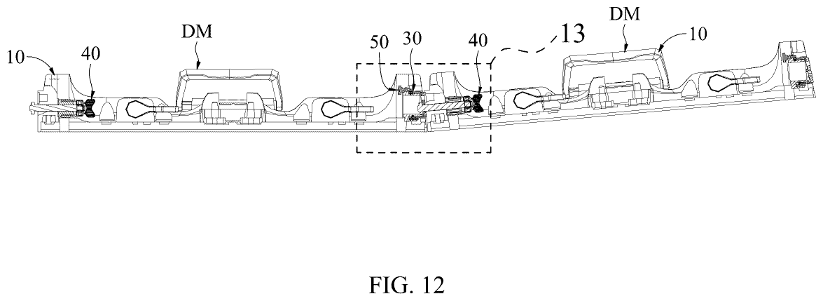

In certain embodiments, the angle limiting assembly 30 is disposed on the first side edge 14 of the box 10. When two display modules DM are spliced, the first side edge 14 of one display module DM is aligned to the second side edge 15 of the other display module DM. Thus, the angle limiting assembly 30 may provide different angles for the second side edge 15 of the other display module DM to abut thereagainst, such that the two display modules DM, after being spliced, may achieve different angular configurations. Referring to FIGS. 7 and 8, FIG. 7 is a plain schematic view of a spliced display according to one embodiment of the present disclosure, illustrating a first schematic view of the angle adjustment of adjacent display modules; and FIG. 8 is a cross-sectional view along the sectional line 8-8 in FIG. 7. Viewing from the viewing angle of FIGS. 7 and 8, the display module DM located at the right side adopts a downward oblique angle based on the variation in the angle limiting assembly 30. Further referring to FIGS. 11 and 12, FIG. 11 is a plain schematic view of a spliced display according to one embodiment of the present disclosure, illustrating a second schematic view of the angle adjustment of adjacent display modules; and FIG. 12 is a cross-sectional view along the sectional line 12-12 in FIG. 11. Viewing from the viewing angle of FIGS. 11 and 12, the display module DM located at the right side adopts an upward oblique angle based on the variation in the angle limiting assembly 30. Referring to FIGS. 3, 4 and 9, FIG. 9 is a partial enlarged schematic view of enclosed location 9 in FIG. 8. The rotation member 31 of the angle limiting assembly 30 is used to rotate to adjust the included angle between the display modules DM. In certain embodiments, the rotation member 31 includes a first body section 311 and a second body section 312 interconnected to each other, and the first body section 311 and the second body section 312 are both hollow cylindrical structures. In these embodiments, a diameter of the first body section 311 is greater than a diameter of the second body section 312. The rotation member 31, with the second body section 312, is rotatably disposed on and running through the first side edge 14 of the box 10 around the second direction D2, and the first body section 311 is located inside the inner side S1 of the box 10 and abuts against the first side edge 14, thus preventing the rotation member 31 from detaching from the box 10.

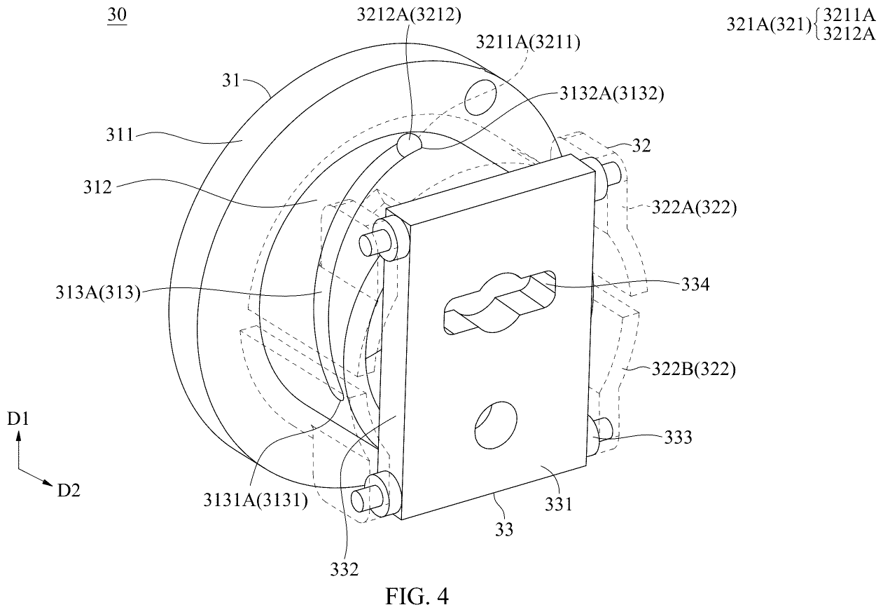

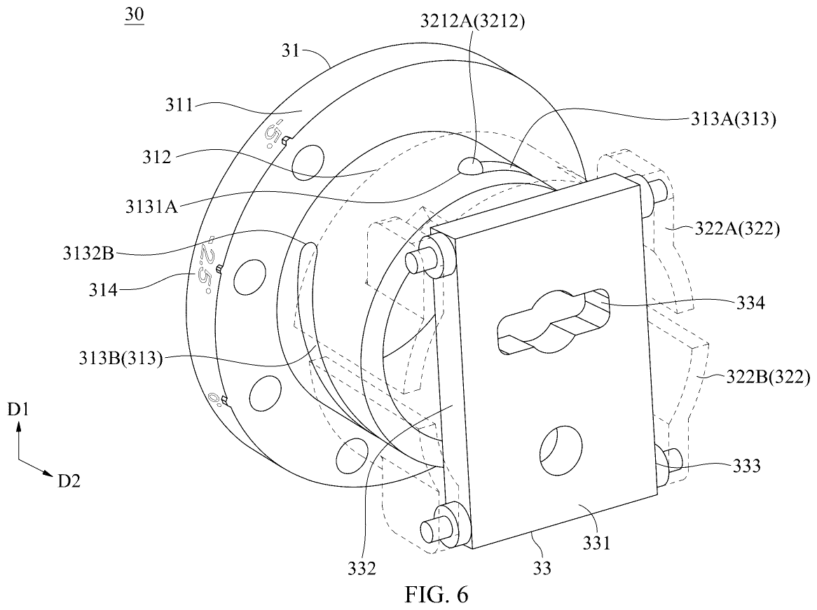

In certain embodiments, the second body section 312 of the rotation member 31 has an outer surface. In these embodiments, the guiding portion 313 is disposed on the outer surface of the second body section 312. In certain embodiments, the guiding portion 313 is a slot structure with two ends located at different locations in the second direction D2. Referring to FIGS. 4 to 6, FIG. 5 is a second usage schematic view of an angle limiting assembly of the display module of a spliced display according to one embodiment of the present disclosure; and FIG. 6 is a third usage schematic view of an angle limiting assembly of the display module of a spliced display according to one embodiment of the present disclosure. In one embodiment as illustrated in FIGS. 4 to 6, the guiding portion 313 extends in an arc shape between the two ends thereof, but the present disclosure is not limited thereto. In other embodiments, the guiding portion 313 may extend in a straight line between the two ends thereof. As such, the guiding portion 313 of the rotation member 31 is used to guide to linkage assembly 32 to move in the second direction D2. Thus, the position difference of the two ends of the guiding portion 313 in the second direction D2 is the movement distance of the linkage assembly 32 in the second direction D2. In other words, the shape and size of the guiding portion 313 may be changed correspondingly based on the movement distance required by the linkage assembly 32.

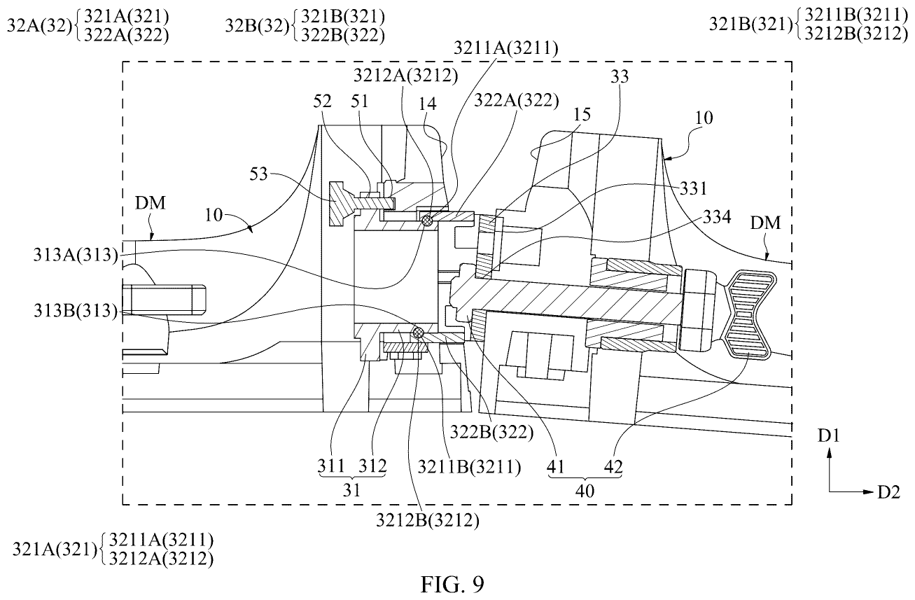

Referring to FIG. 9, the linkage assembly 32 abuts against the guiding portion 313 of the rotation member 31 to be guided by the guiding portion 313 and to change the location of the linkage assembly 32 in the second direction D2. In certain embodiments where the guiding portion 313 is a slot, the linkage assembly 32 includes a linkage portion 321 and a swing arm 322. In the embodiments, the linkage portion 321 is disposed on the swing arm 322 to match with the guiding portion 313 to drive the swing arm 322 to linearly move.

Referring to FIG. 9, in certain embodiments, the linkage portion 321 is a combination of a recess 3211 and a rolling ball 3212. The recess 3211 is disposed on a surface of the swing arm 322, the swing arm 322 covers and is disposed on the second body section 312 of the rotation member 31, and the rolling ball 3212 is rollably disposed between the guiding portion 313 of the rotation member 31 and the recess 3211. Thus, when the rotation member 31 rotates, different positions of the guiding portion 313 of the rotation member 31 correspond to the rolling ball 3212, such that the rolling ball 3212 changes its position corresponding to the guiding portion 313, and when the rolling ball 3212 changes its position, it simultaneously drives the swing arm 322 to change its position. Since the two ends of the guiding portion 313 are located at different positions in the second direction D2, the swing arm 322 may be simultaneously driven to change its position in the second direction D2.

Referring to FIGS. 3 and 9, in certain embodiments, the swing arm 322 includes a sleeving portion 3222 and two position limiting portions 3223. The sleeving portion 3222 is a semi-circular ring sheet structure, and each position limiting portion 3223 is a rectangular plate sheet structure. In these embodiments, the shape of the sleeving portion 3222 is formed to surround the second direction D2, and each position limiting portion 3223 is disposed in parallel at one end of the sleeving portion 3222 in the second direction D2. Thus, the recess 3211 of the linkage portion 321 is located on a surface of the sleeving portion 3222, the swing arm 322 sleeves over the second body section 312 of the rotation member 31 by the surface of the sleeving portion 3222 having the recess 3211, and each position limiting portion 3223 abuts against the box 10 to limit the rotation of the swing arm 322.

Referring to FIG. 3, in certain embodiments, the first side edge 14 of the box 10 has a through hole 141 and a position limiting slot 142. The through hole 141 runs through the first side edge 14. The position limiting slot 142 is adjacent to an end of the through hole 141 closer to the outer side S2, and the position limiting slot 142 extends along the second direction D2 and is open to the outer side S2 of the box 10. In these embodiments, the second body section 312 of the rotation member 31 is rotatably disposed in the through hole 141, and each position limiting portion 3223 of the swing arm 322 is accommodated in the position limiting slot 142. Thus, when the rotation member 31 rotates, the swing arm 322, due to the limitation of the position limiting portions 3223, is limited to be only capable of linearly moving along the second direction D2, thereby ensuring the swing arm 322 to indeed drive the connector 33 to change the angle.

Referring to FIGS. 3 and 4, the connector 33 is used to change the angle with the linkage assembly 32 and to abut against an adjacent display module DM to change the included angle between the two adjacent display modules DM. In certain embodiments, the connector 33 is a plate sheet structure. In these embodiments, the connector 33 has an abutting surface 331 and a first side surface 332 and a second side surface 333 opposite to each other. The abutting surface 331 is connected between the first side surface 332 and the second side surface 333, and one end of each of the first side surface 332 and the second side surface 333 is pivoted to the swing arm 322. Thus, the connector 33 abuts against the box 10 of the other display module DM by the abutting surface 331, and when the swing arm 322 moves along the second direction D2, it drives the connector 33 to pivotally swing and generate an angle change, thereby changing the included angle between the two adjacent boxes 10.

Referring to FIGS. 4 to 6, in certain embodiments, two guiding portions 311 are provided in the rotation member 31, and the quantity of the linkage assemblies 32 corresponds to the quantity of the guiding portions 311. In these embodiments, one of the guiding portions 311 is located within a 180° central angle range of the outer surface of the second body section 312, and the other of the guiding portions 311 is located within the other 180° central angle range of the outer surface of the second body section 312 (that is, an opposite location in the circumference). Thus, each linkage assembly 32 may be driven by each guiding portion 313 to move, and the two ends of the first side surface 332 and the second side surface 333 of the connector 33 may be respectively pivoted to the swing arms 322 of the linkage assemblies 32, thereby enhancing the movement stability of the linkage assemblies 32 and the connector 33.

It should be noted that, in certain other embodiments, the shape, quantity and distribution of the guiding portion 313 of the rotation member 31 may be determined according to the angle required by the connector 33. For example, an increase of the distance between the two ends of the guiding portion 313 in the second direction D2 may increase the angle changing range of the connector 33, and the increase of the distance between the two ends of the guiding portion 313 in the second direction D2 correspondingly changes the shape between the two ends of the guiding portion 313. Thus, the shape and distribution of the guiding portion 313 is not limited to the aforementioned embodiments.

Referring to FIGS. 4 to 6, in certain embodiments where two guiding portions 311 are provided in the rotation member 31, each guiding portion 311 of the rotation member 31 is located at a different position in the first direction D1. For clear descriptions, the guiding portions 313 are respectively referred to as an upper guiding portion 313A and a lower guiding portion 313B. The upper guiding portion 313A has a first end 3131A and a second end 3132A, and the lower guiding portion 313B has a first end (not shown in the figures) and a second end 3132B. The first end 3131 is away from the first body section 311 relative to the second end 3132, and viewing from a circumferential location of the second body section 312, the first end 3131A of the upper guiding portion 313A is close to the second end 3132B of the lower guiding portion 313B.

Referring to FIGS. 4 to 6 and 9, in these embodiments, each guiding portion 313 matches with a linkage assembly 32. Thus, two linkage assemblies 32 are provided. For clear descriptions, the linkage assemblies 32 are respectively referred to as an upper linkage assembly 32A and a lower linkage assembly 32B. The upper linkage assembly 32A includes an upper linkage portion 321A and an upper swing arm 322A, and the lower linkage assembly 32B includes a lower linkage portion 321B and a lower swing arm 322B. The upper linkage portion 321A includes an upper recess 3211A and an upper rolling ball 3212A, and the lower linkage portion 321B includes a lower recess 3211B and a lower rolling ball 3212B. The upper rolling ball 3212A of the upper linkage portion 321A is accommodated in the upper guiding portion 313A, and the lower rolling ball 3212B of the lower linkage portion 321B is accommodated in the lower guiding portion 313B.

It should be noted that the linkage portion 321 of the aforementioned embodiments is described using the recess 3211 and the rolling ball 3212 as the example, but the present disclosure is not limited thereto. In other embodiments, the linkage portion 321 may be a round protrusion or a protruding column integral to the swing arm 322 or a rivet fixedly connected to the swing arm 322.

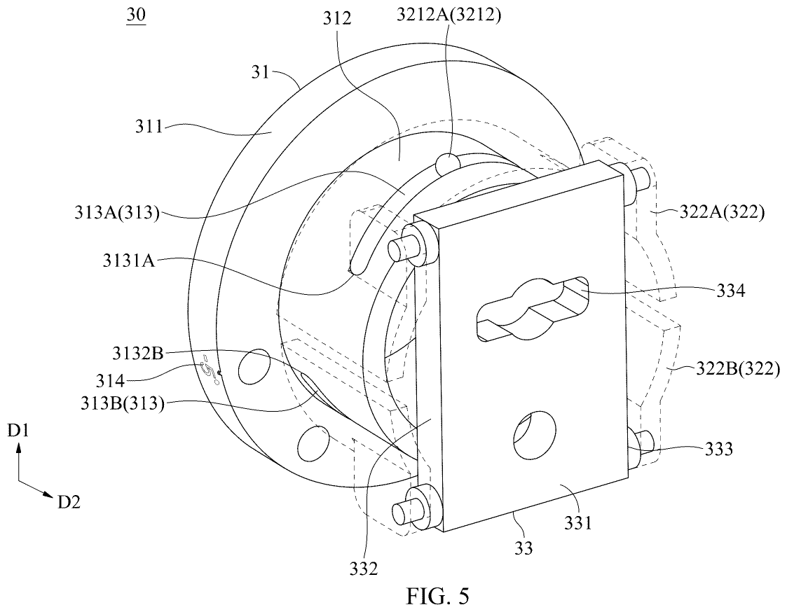

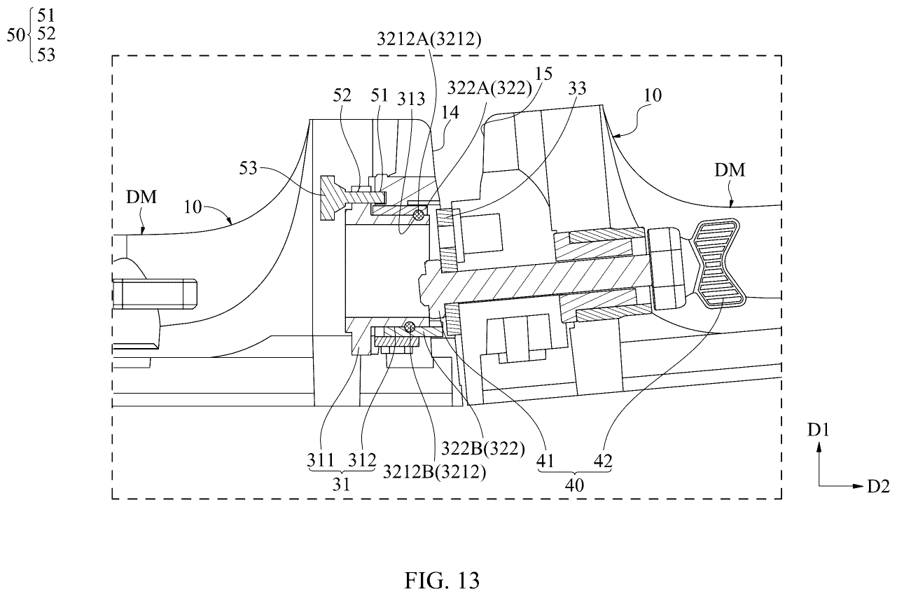

Referring to FIGS. 4 to 6, 9 and 13, FIG. 13 is a partial enlarged schematic view of enclosed location 13 in FIG. 12. Viewing from the viewing angle of FIGS. 4 to 6, in certain embodiments where each guiding portion 313 is disposed on the relative positions of the circumference of the second body section 312, when the connector 33 is in a straight state perpendicular to the second direction D2, the linkage portion 321 of each linkage assembly 32 is located at a position between the two ends of each guiding portion 313 (as shown in the state of FIG. 5). When the rotation member 31 rotates clockwise (from the state of FIG. 5 to the state of FIG. 6), the first end 3131A of the upper guiding portion 313A gradually becomes closer to the upper rolling ball 3212A, and the first end of the lower guiding portion 313B gradually becomes closer to the lower rolling ball 3212B (that is, the second end 3132B of the lower guiding portion 313B gradually becomes farther away from the lower rolling ball 3212B). Thus, the upper swing arm 322A and the lower swing arm 322B are simultaneously driven to move away from the first body section 311 of the rotation member 31. In contrast, when the rotation member 31 rotates counterclockwise (from the state of FIG. 5 to the state of FIG. 4), the second end 3132A of the upper guiding portion 313A gradually becomes closer to the upper rolling ball 3212A, and the second end 3132B of the lower guiding portion 313B gradually becomes closer to the lower rolling ball 3212B, such that the upper swing arm 322A and the lower swing arm 322B are simultaneously driven to move closer to the first body section 311 of the rotation member 31 (as shown in the state of FIG. 13).

In these embodiments, a distance between the first end 3131A and the second end 3132A of the upper guiding portion 313A in the second direction D2 is less than a distance between the first end and the second end 3132B of the lower guiding portion 313B in the second direction D2. Thus, when the rotation member 31 rotates, a distance of the lower swing arm 322B moving along the second direction D2 driven by the lower guiding portion 313B is greater than a distance of the upper swing arm 322A moving along the second direction D2 driven by the upper guiding portion 313A, such that the two ends of the connector 33 is in a bevel shape.

It should be noted that the configurations of the guiding portions 313 are not limited to the aforementioned embodiments. In other embodiments, with the different positions or directions of the guiding portions 313, the upper swing arm 322A and the lower swing arm 322B may be driven to move in opposite directions to achieve the beveled shape of the connector 33.

Referring to FIG. 3, in certain embodiments, the angle limiting assembly 30 further includes a compressive assembly 34. The compressive assembly 34 is disposed at the inner side S1 of the box 10 and compresses and abuts against a side of the swing arm 322 away from the rotation member 31 along the first direction D1. In these embodiments, the compressive assembly 34 includes a pressing member 341 and a locking member 342. The pressing member 341 includes a first portion 3411 and a second portion 3412 connected to each other. The first portion 3411 is a planar structure, and the second portion 3412 is a round arch structure. The second portion 3412 is located on a surface of the first portion 3411. Thus, the second portion 3412 of the pressing member 341 abuts against the sleeving portion 3222 of the swing arm 322, and the first portion 3411 abuts against the box 10. The locking member 342 extends along the first direction D1 to be locked to the first portion 3411 to compress and abut against the swing arm 322 and the rotation member 31, thus providing a suitable positioning force for the swing arm 322 and the rotation member 31, preventing the swing arm 322 from moving along the second direction D2 and detaching, and enhancing the stability of the entire structure.

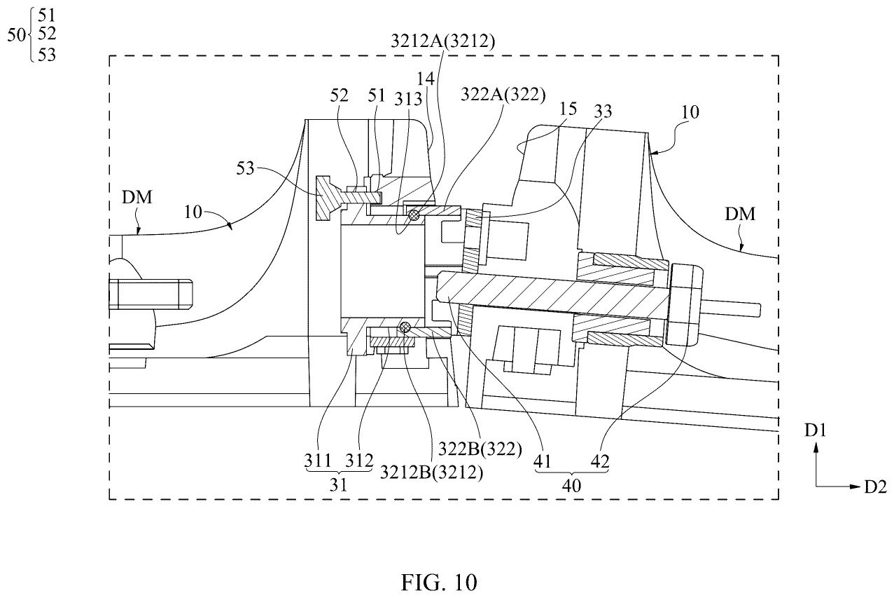

Referring to FIGS. 9 and 10, FIG. 10 is a state schematic view of the fixing member in FIG. 9 being released. In certain embodiments, the spliced display further includes a fixing member 40. In these embodiments, the angle limiting assembly 30 is located on the first side edge 14, and the fixing member 40 is rotatably disposed on the second side edge 15. The first side edge 14 of one of the display modules DM abuts against the second side edge 15 of another adjacent display module DM, and the fixing member 40 fixes the two adjacent display modules DM.

Referring to FIGS. 3, 4, 9 and 10, in certain embodiments where the spliced display includes the fixing member 40, the connector 33 of the angle limiting assembly 30 further includes a combining hole 334, and the combining hole 334 runs through the abutting surface 331. In addition, the two ends of the fixing member 40 are respectively a combining end 41 and a locking end 42. The shape of the combining end 41 is identical to the shape of the combining hole 334, and the locking end 42 is used for operation to fix the fixing member 40 to the second side edge 15 of the box 10.

Referring to FIGS. 3, 4, 9 and 10, in certain embodiments, the combining hole 334 is a “+”-shaped through hole, the combining end 41 of the fixing member 40 is a “+”-shaped structure, and the locking end 42 may be, without being limited to, a quick-release locking assembly through rotation and eccentric compression. In these embodiments, when two boxes 10 are to be securely connected, the first side edge 14 of one box 10 is moved close to the second side edge 15 of the other box 10, and then the locking end 42 of the fixing member 40 is released, such that the fixing member 40 is released to be capable of rotating freely. Then, the fixing member 40 is rotated, such that the shape of the combining end 41 of the fixing member 40 corresponds to the shape of the combining hole 334 of the box 10, and the combining end 41 passes through the combining hole 334 of the box 10 (as shown in the state of FIG. 10). After the combining end 41 of the fixing member 40 passes through the combining hole 334, the fixing member 40 is again rotated, such that the shape of the combining end 41 of the fixing member 40 does not correspond to the shape of the combining hole 334 of the box 10 (as shown in the state of FIG. 9). Thus, the fixing member 40 is limited, such that the two boxes 10 are not separated. In this case, the locking end 42 may be used to lock the fixing member 40, such that the fixing member 40 is locked and in a non-rotatable state, preventing the fixing member 40 from free rotation and being released, and thereby further enhancing the stability of the two boxes 10.

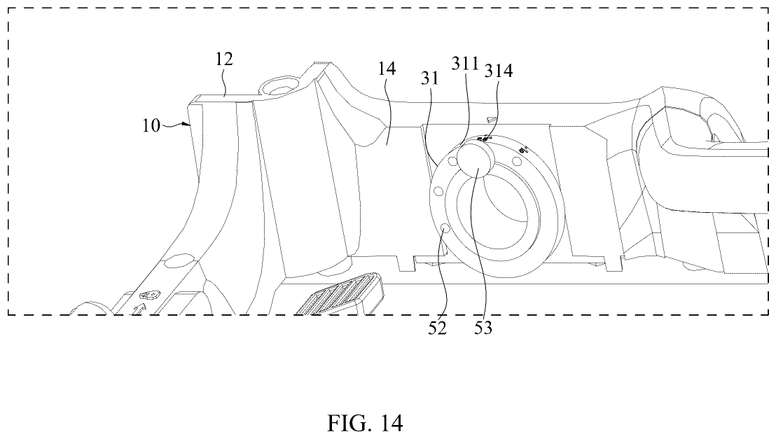

Referring to FIGS. 2, 13 and 14, in certain embodiments, the spliced display further includes a positioning module 50. In certain embodiments, the positioning module 50 includes a first positioning hole 51, a plurality of second positioning holes 52 and a pin 53. In these embodiments, the first positioning hole 51 is disposed on the first side edge 14 of the box 10, each second positioning hole 52 is disposed on and running through the first body section 311 of the rotation member 31 along the second direction D2, and the pin 53 passes through one of the second positioning holes 52 and the first positioning hole 51 to fix the rotation member 31 at different angular positions. In certain embodiments, the second position holes 52 are arranged equally divided by central angles along the circumference of the first body section 311, thereby providing a user with various angle options. In certain embodiments, the rotation member 31 further includes a plurality of marking portions 314. The marking portions 314 are disposed on the circumferential surface of the first body section 311 of the rotation member 31 and correspond to the positions of the second positioning holes 52, thereby enabling the operator to identify the currently adjusted angle based on the marking portions 314. In certain embodiments, the marking portions 314 may include, without being limited thereto, angle symbols (e.g., 2.5°).

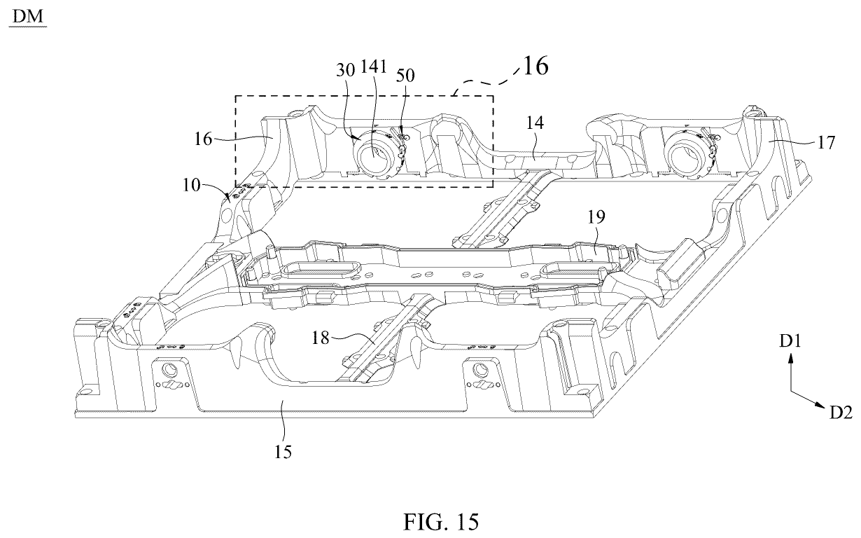

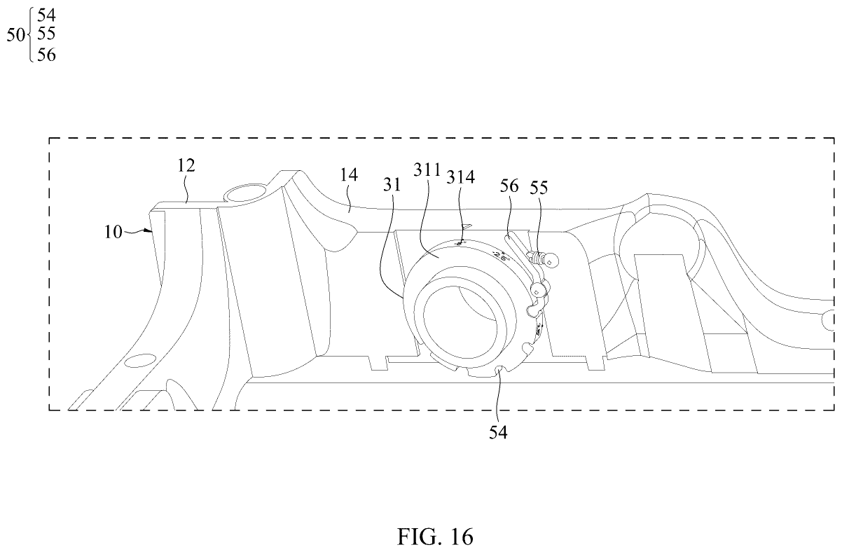

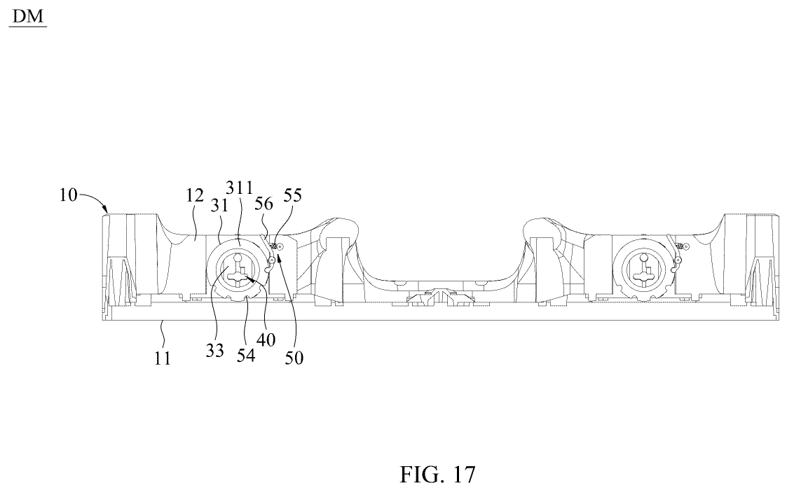

The positioning module 50 of the spliced display is not limited to the aforementioned embodiment. Referring to FIGS. 15 to 17, FIG. 15 is a schematic view of a display module of a spliced display according to one embodiment of the present disclosure, illustrating the display module including a positioning module capable of performing automatic positioning; FIG. 16 is a partial enlarged schematic view of enclosed location 16 in FIG. 15; and FIG. 17 is a partial plain view of FIG. 15. In certain embodiments, the positioning module 50 includes a plurality of positioning slots 54, an elastic body 55 and a positioning member 56. In these embodiments, the positioning slots 54 are disposed at intervals on the circumference of the first body section 311 of the rotation member 31. One end of the elastic body 55 is fixed to the first side edge 14 of the box 10. One end of the positioning member 56 is connected to the other end of the elastic body 55, and the other end of the positioning member 56 is detachably accommodated in one of the positioning slots 54. The portion between the two ends of the positioning member 56 is then pivoted to the first side edge 14 of the box. In this case, the elastic body 55 is a stretchable spring.

Thus, one end of the positioning member 56 is normally pulled by the elastic body 55, such that the other end of the positioning member 56 is normally accommodated in one of the positioning slots 54. When the angle of the connector 33 needs to be changed, the end of the positioning member 56 connected to the elastic body 55 is pressed, such that the positioning member 56 stretches the elastic body 55 and stores the elastic force, and simultaneously drives the positioning member 56 to pivotally rotate, such that the other end of the positioning member 56 is detached from the corresponding positioning slot 54. In this state, the rotation member 31 loses its positioning force, allowing the operator to rotate it and thereby change the angle of the connector 33. Once the operation of the rotation member 31 is complete, the operator can simply release the force applied to the end of the positioning member 56 connected to the elastic body 55. The clastic body 55 then releases the elastic force and returns to its original position, and the other end of the positioning member 56 is re-accommodated in the corresponding positioning slot 54 for positioning of the rotation member 31, thus providing more convenient operation.

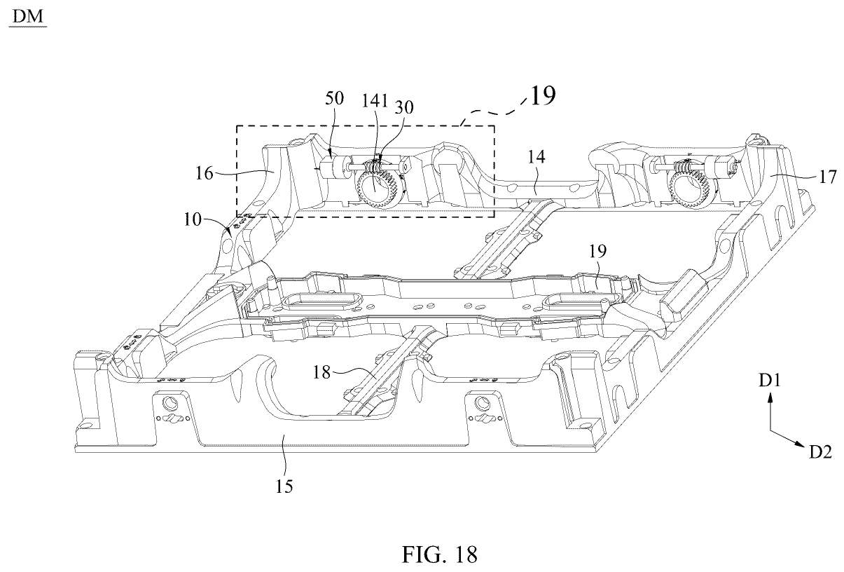

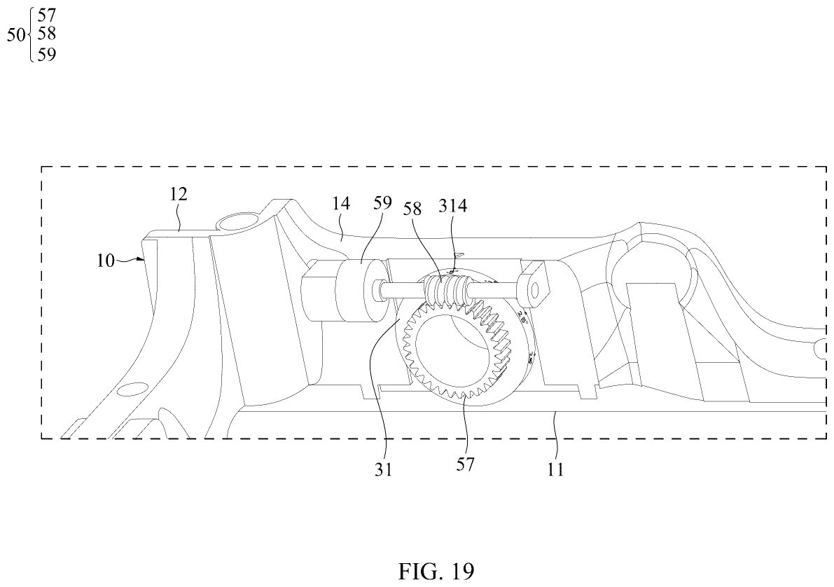

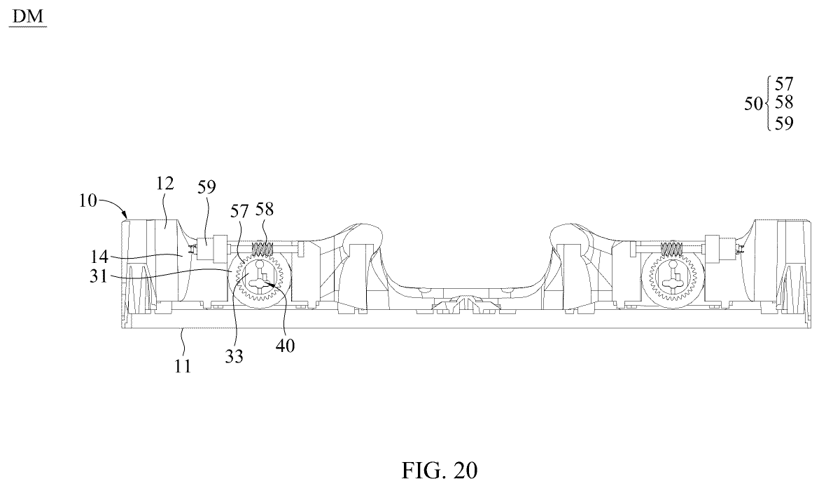

Referring to FIGS. 18 to 20, FIG. 18 is a schematic view of a display module of a spliced display according to one embodiment of the present disclosure, illustrating a positioning module capable of freely adjusting the angle; FIG. 19 is a partial enlarged schematic view of enclosed location 19 in FIG. 18; and FIG. 20 is a partial plain view of FIG. 18. In certain embodiments, the positioning module 50 includes a plurality of teeth 57, a worm gear 58 and a driving source 59. In these embodiments, each of the teeth 57 is disposed along the circumferential surface of the first body section 311 of the rotation member 31, the driving source 59 is fixedly disposed on the box 10, and the worm gear 58 extends along the second direction D2 to be connected to the driving source 59 and engages with the teeth 57. When the drive source 59 drives the worm gear 58 to rotate, the worm gear 58 engages with the teeth 57 to drive the rotation member 31 to rotate, thereby changing the included angle between the connector 33 and the two adjacent boxes 10. Thus, the drive source 59 may drive the rotation member 31 to rotate and change the angle of the connector 33. Compared to the case where the second positioning holes or the positioning slot are pre-provided with specific angles and specific quantities, the embodiments may offer greater flexibility in angle adjustment, satisfying a wider range of options. In addition, the drive source 59 may drive the rotation member 31 to rotate and change the angle of the connector 33, without the need for manual operation, thus providing a more labor-saving operation.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A spliced display, comprising:
a plurality of display modules, respectively comprising:
a box, comprising a display side and a back side opposite to each other, wherein a direction perpendicularly connected to the display side and the back side is defined as a first direction; and
a display, detachably disposed on the display side of the box; and
at least one angle limiting assembly, comprising:
a rotation member, rotatably disposed on the box around a second direction perpendicular to the first direction, wherein the rotation member has a guiding portion, and two ends of the guiding portion are located at different positions in the second direction;
a linkage assembly, comprising a linkage portion, wherein the linkage assembly is disposed on the rotation member, and when the rotation member rotates, the linkage portion is guided by the guiding portion to linearly move along the second direction; and
a connector, connected to the linkage assembly, wherein each of the display modules abuts against an adjacent one of the display modules by the connector.

2. The spliced display according to claim 1, further comprising a fixing member, wherein the box comprises a first side edge and a second side edge opposite to each other, the angle limiting assembly is located on the first side edge, the fixing member is disposed on the second side edge, the first side edge of one of the display modules abuts against the second side edge of the adjacent one of the display modules, and the fixing member fixes two adjacent ones of the display modules.

3. The spliced display according to claim 1, wherein the guiding portion is a slot, the linkage assembly further comprises a swing arm, the linkage portion comprises a recess and a rolling ball, the recess is disposed on the swing arm, the rolling ball is rollably disposed within the guiding portion, and the swing arm sleeves over the rolling ball via the recess.

4. The spliced display according to claim 2, wherein a side of the first side edge of the box facing toward the second side edge is an inner side, the other side of the first side edge is an outer side, the rotation member comprises a first body section and a second body section interconnected to each other, the first body section abuts against the inner side of the first side edge, and the second body section is disposed on the first side edge.

5. The spliced display according to claim 4, wherein the first side edge of the box further comprises a position limiting slot, the position limiting slot extends along the second direction and is open at the outer side of the box, the linkage assembly further comprises a swing arm, the swing arm has a position limiting portion, and the position limiting portion is movably accommodated in the position limiting slot along the second direction.

6. The spliced display according to claim 5, wherein the angle limiting assembly further comprises a compressive assembly disposed at the inner side and abutting against a side of the swing arm away from the rotation member, and the compressive assembly compresses the swing arm and the rotation member along the first direction.

7. The spliced display according to claim 1, wherein the guiding portion is a slot.

8. The spliced display according to claim 1, further comprising a positioning module, disposed between the box and the rotation member to position the rotation member.

9. The spliced display according to claim 8, wherein the positioning module comprises a first positioning hole, a plurality of second positioning holes and a pin, the first positioning hole is disposed on the box, each of the second positioning holes is disposed on the rotation member, and the pin passes through one of the second positioning holes and the first positioning hole to fix the rotation member at different angular positions.

10. The spliced display according to claim 8, wherein the positioning module comprises a plurality of positioning slots, an elastic body and a positioning member, the positioning slots are disposed on a peripheral surface of the rotation member, one end of the elastic body is fixed to the box, one end of the positioning member is connected to the other end of the elastic body, the other end of the positioning member is detachably accommodated in one of the positioning slots, and a position between the two ends of the positioning member is pivoted to the box.

11. The spliced display according to claim 8, wherein the positioning module comprises a plurality of teeth, a worm gear and a driving source, each of the teeth is disposed along a peripheral surface of the rotation member, the driving source is fixed to the box, and the worm gear is connected to the driving source and engages with the teeth on the rotation member.
